(19) United States
(12) Patent Application Publication
(10) Pub. No.: US 2023/0403826 A1
(43) Pub. Date: Dec. 14, 2023

(54) HEAT DISSIPATION SUBSTRATE

(71) Applicant: Subtron Technology Co., Ltd., Hsinchu County (TW)

(72) Inventors: Chung Ying Lu, Hsinchu County (TW); Tzu-Shih Shen, Hsinchu County (TW); Chien-Hung Wu, Hsinchu County (TW)

(73) Assignee: Subtron Technology Co., Ltd., Hsinchu County (TW)

(21) Appl. No.: 17/860,076

(22) Filed: Jul. 7, 2022

(30) Foreign Application Priority Data
Jun. 10, 2022 (TW) 111121718

(51) Int. Cl. H05K 7/20; H05K 1/03; H05K 1/02

(52) U.S. Cl. CPC H05K 7/20409; H05K 1/0306; H05K 1/0212

(57) ABSTRACT

A heat dissipation substrate includes heat dissipation blocks, an insulation filling structure, a first insulating layer, and a first circuit layer. Each heat dissipation block includes a first surface and a second surface opposite to the first surface. The insulation filling structure is disposed between the heat dissipation blocks to laterally connect the heat dissipation blocks. A first insulating surface of the insulation filling structure is substantially coplanar with the first surface of the heat dissipation block. A second insulating surface of the insulation filling structure is substantially coplanar with the second surface of the heat dissipation block. The first insulating layer is disposed on the first surface. The first circuit layer is disposed on the first insulating layer and penetrates the first insulating layer to be connected with the heat dissipation blocks. A thickness of the heat dissipation blocks is greater than a thickness of the first circuit layer.

### CROSS-REFERENCE TO RELATED APPLICATION

This application claims the priority benefit of Taiwanese application no. 111121718, filed on Jun. 10, 2022. The entirety of the above-mentioned patent application is hereby incorporated by reference herein and made a part of this specification.

### BACKGROUND

### Technical Field

The disclosure relates a substrate structure, and in particular, to a heat dissipation substrate.

### Description of Related Art

With the development of science and technology, electronic devices are trending toward miniaturization. To reduce dimensions of the electronic devices, packaging with closeness between elements is required, while a great amount of heat is thus accumulated in the package, influencing performance of the devices due to overheat. To improve heat dissipation, a heat dissipation material is generally embedded in a support substrate to help heat dissipation from elements, which has a complicated manufacturing process. Therefore, how to effectively dissipate heat from elements in a limited space and reduce cost is currently an issue to be addressed.

### SUMMARY

The disclosure provides a heat dissipation substrate, having good support and heat dissipation, and reducing manufacturing cost.

A heat dissipation substrate according to an embodiment of the disclosure includes a plurality of heat dissipation block, an insulation filling structure, a first insulating layer, and a first circuit layer. Each of the plurality of heat dissipation blocks includes a first surface and a second surface opposite to the first surface. The insulation filling structure is disposed between the plurality of heat dissipation blocks to laterally connect the plurality of heat dissipation blocks. The insulation filling structure has a first insulating surface and a second insulating surface opposite to the first insulating surface. The first insulating surface of the insulation filling structure is substantially coplanar with the first surfaces of the plurality of heat dissipation blocks. The second insulating surface of the insulation filling structure is substantially coplanar with the second surfaces of the plurality of heat dissipation blocks. The first insulating layer is disposed on the first surfaces of part of the plurality of heat dissipation blocks and the first insulating surface of the insulation filling structure. The first circuit layer is disposed on the first insulating layer and penetrates the first insulating layer to be connected with the plurality of heat dissipation blocks. A thickness of the plurality of heat dissipation blocks is greater than a thickness of the first circuit layer.

In an embodiment of the disclosure, the thickness of the plurality of heat dissipation blocks is between 50 μm and 200 μm, and the thickness of the first circuit layer is between 15 μm and 35 μm.

In an embodiment of the disclosure, a material of the plurality of heat dissipation blocks includes copper or aluminum.

In an embodiment of the disclosure, the heat dissipation substrate further includes a second circuit layer. The second circuit layer is disposed on the second surfaces of part of the plurality of heat dissipation blocks.

In an embodiment of the disclosure, the second circuit layer includes a first opening. The first opening exposes at least the second insulating surface of part of the insulation filling structure.

In an embodiment of the disclosure, the first insulating layer includes a second opening, and the first circuit layer includes a third opening. The second opening and the third opening correspond to each other and expose the first surfaces of part of the plurality of heat dissipation blocks.

In an embodiment of the disclosure, a sidewall of the second opening of the first insulating layer and a sidewall of the third opening of the first circuit layer are substantially aligned.

In an embodiment of the disclosure, part of the plurality of heat dissipation blocks are not connected to the first circuit layer and the second circuit layer.

In an embodiment of the disclosure, a cross-sectional shape of the insulation filling structure includes a rectangle or a trapezoid.

In an embodiment of the disclosure, a material of the plurality of heat dissipation blocks and a material of the first circuit layer are the same.

Based on the foregoing, in the heat dissipation substrate according to the embodiments of the disclosure, the package structure can be provided with good support and heat dissipation in the application to the packaging process. In addition, since it is not required to use a conventional support substrate, the manufacturing cost can be reduced. Moreover, flexible wiring design may be performed in accordance with the requirements of different packaging elements or heat-generating elements in the package structure.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic cross-sectional view of a heat dissipation substrate according to an embodiment of the disclosure.

FIG. 2 is a schematic cross-sectional view of a heat dissipation substrate according to another embodiment of the disclosure.

FIG. 3 is a schematic cross-sectional view of a heat dissipation substrate according to another embodiment of the disclosure.

FIG. 4 is a schematic cross-sectional view of a heat dissipation substrate according to another embodiment of the disclosure.

### DESCRIPTION OF THE EMBODIMENTS

Directional terms, such as “above”, “below”, “front”, “rear”, “left”, an “right” mentioned herein refer to only the directions of the drawings. Accordingly, the directional terms as used serve for describing, instead of limiting, the disclosure.

In the drawings, each figure illustrates general characteristics of methods, structures, and/or materials used in particular embodiments. Nonetheless, the drawings should not be interpreted as defining or limiting the scope or nature covered by these embodiments. For example, relative dimensions, thicknesses, and positions of various layers, regions, and/or structures may be reduced or enlarged for clarity.

In the following embodiments, the same or similar reference numerals will be used for the same or similar elements, and repeated descriptions thereof will be omitted. In addition, non-conflicting features in different embodiments can be combined with one another, and simple equivalent changes and modifications made based on the specification or the claims fall within the scope of the disclosure.

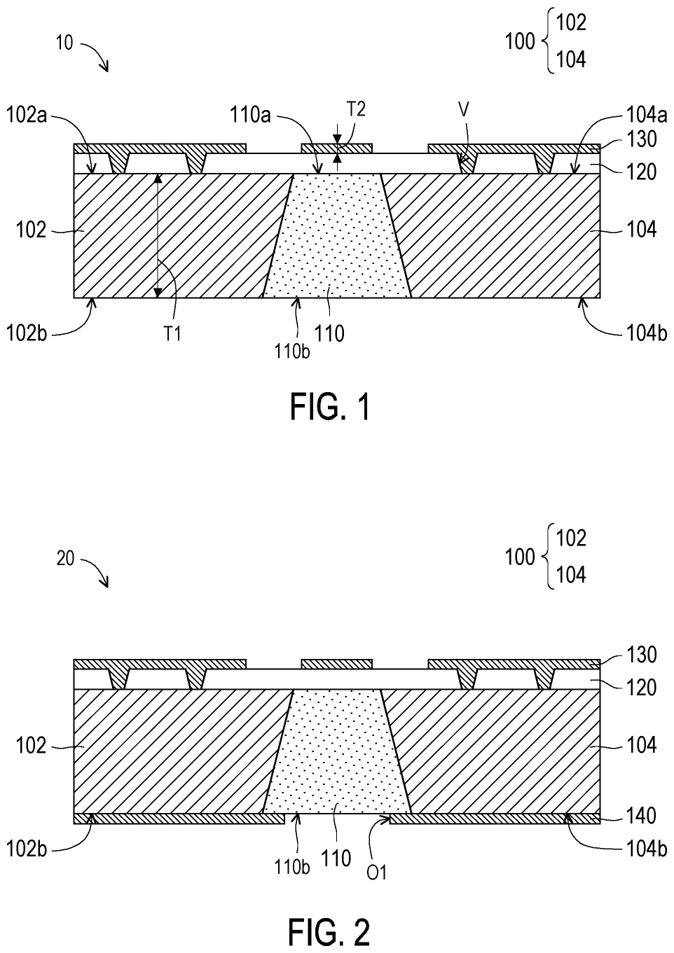

FIG. 1 is a schematic cross-sectional view of a heat dissipation substrate according to an embodiment of the disclosure.

With reference to FIG. 1, a heat dissipation substrate 10 includes a plurality of heat dissipation blocks 100, an insulation filling structure 110, a first insulating layer 120, and a first circuit layer 130. Each of the plurality of heat dissipation blocks 100 includes a first surface and a second surface opposite to the first surface. For example, the plurality of heat dissipation blocks 100 may include heat dissipation blocks 102 and 104. The heat dissipation block 102 includes a first surface 102a and a second surface 102b opposite to the first surface 102a, and the heat dissipation block 104 includes a first surface 104a and a second surface 104b opposite to the first surface 104a. The insulation filling structure 110 is disposed between the plurality of heat dissipation blocks 100 to laterally connect the plurality of heat dissipation blocks 100. The insulation filling structure 110 has a first insulating surface 110a and a second insulating surface 110b opposite to the first insulating surface 110a. The first insulating surface 110a of the insulation filling structure 110 is substantially coplanar with the first surfaces of the plurality of heat dissipation blocks 100 (e.g., the first surface 102a of the heat dissipation block 102 and the first surface 104a of the heat dissipation block 104), and the second insulating surface 110b of the insulation filling structure 110 is substantially coplanar with the second surfaces of the plurality of heat dissipation blocks 100 (e.g., the second surface 102b of the heat dissipation block 102 and the second surface 104b of the heat dissipation block 104). The first insulating layer 120 is disposed on the first surfaces of the plurality of heat dissipation blocks 100 and the first insulating surface 110a of the insulation filling structure 110. The first circuit layer 130 is disposed on the first insulating layer 120 and penetrates the first insulating layer 120 to be connected with the plurality of heat dissipation blocks 100. A thickness T1 of the plurality of heat dissipation blocks 100 is greater than a thickness T2 of the first circuit layer 130.

The heat dissipation block 100 may include a metal with a thermal conductivity of 200 to 500 W/m*K, such as copper, aluminum, or other suitable metals. In an embodiment, a material of the heat dissipation block 100 is copper.

A material of the insulation filling structure 110 may include an organic material or an inorganic material. For example, the organic material is epoxy resin, polyester resin, and polyimide among other organic materials, and the inorganic material is ceramic, silicon, and silicon carbide among other inorganic materials, but the disclosure is not limited thereto.

In some embodiments, the plurality of heat dissipation blocks 100 are separated from each other by the insulation filling structure 110 and are not in contact with each other.

In an embodiment, a cross-sectional shape of the insulation filling structure 110 may be a trapezoid, but the disclosure is not limited thereto. In other embodiments, the cross-sectional shape of the insulation filling structure 110 may be a rectangle or other shapes.

Although only one insulation filling structure 110 and the two heat dissipation blocks 102 and 104 are shown in this embodiment, they are not intended to limit the disclosure. The number of insulation filling structures and the number of heat dissipation blocks may be adjusted depending on the actual requirements.

A material of the first insulating layer 120 may be an insulating material with adhesive properties, such as polypropylene resin, epoxy resin, phenolic resin, or other suitable insulating materials. Accordingly, the plurality of heat dissipation blocks 100 and the insulation filling structure 110 may be connected through the first insulating layer 120 to be integrated into one piece.

In some embodiments, the material of the first insulating layer 120 and the material of the insulation filling structure 110 may be the same, but the disclosure is not limited thereto. In other embodiments, the material of the first insulating layer 120 and the material of the insulation filling structure 110 may be different.

In some embodiments, the first insulating layer 120 may have a via V to expose part of the heat dissipation block 100. Accordingly, the first circuit layer 130 may be connected to the heat dissipation block 100 through the via V. A material of the first circuit layer 130 may be metal, such as copper, gold, silver, aluminum, and the like. In an embodiment, the material of the first circuit layer 130 is copper.

In some embodiments, the material of the first circuit layer 130 and the material of the heat dissipation block 100 may be the same, but the disclosure is not limited thereto. In other embodiments, the material of the first circuit layer 130 and the material of the heat dissipation block 100 may be different.

FIG. 1 schematically shows only the first circuit layer 130, but it is not intended to limit the disclosure. The wiring design of the first circuit layer 130 may be adjusted depending on the actual requirements. For example, a part of the first circuit layer 130 may serve as a signal conduction path between elements, and another part of the first circuit layer 130 may serve as a heat dissipation path.

Since the heat dissipation substrate 10 includes a plurality of separated heat dissipation blocks, a plurality of packaging elements or heat-generating elements may be provided for heat dissipation in the application to the packaging process. For example, two packaging elements or heat-generating elements (not shown) may be disposed respectively on the first circuit layers 130 corresponding to the heat dissipation blocks 102 and 104. The heat generated by the two packaging elements or heat-generating elements may be transferred to the heat dissipation blocks 102 and 104 respectively through the corresponding first circuit layers 130 to be dissipated. Nonetheless, the disclosure is not limited thereto. A single packaging element or heat-generating element may also extend across the plurality of heat dissipation blocks 100 and dissipate heat by the plurality of heat dissipation blocks 100.

In some embodiments, a ratio of the thickness T1 of the heat dissipation block 100 to the thickness of the first circuit layer 130 (i.e., T1/T2) may be between 1.4 and 14. For example, the thickness T1 of the heat dissipation block 100 may be between 50 μm and 200 μm, and the thickness T2 of the first circuit layer 130 may be between 15 μm and 35 μm. Accordingly, the plurality of heat dissipation blocks 100 has a sufficient thickness to serve to support the heat dissipation substrate 10, and provide heat dissipation. In other words, in the heat dissipation substrate 10 of the embodiment, the package structure can be provided with a certain support and heat dissipation in the application to the packaging process. In addition, since it is not required to use a conventional support substrate, the manufacturing cost can be reduced. Moreover, since the first circuit layer 130 is a thin circuit, wiring design may be performed in accordance with the requirements of different packaging elements or heat-generating elements in the package structure, thus improving application flexibility of the heat dissipation substrate 10.

FIG. 2 is a schematic cross-sectional view of a heat dissipation substrate according to another embodiment of the disclosure. It should be noted here that the reference numerals and part of the contents of the embodiment of FIG. 1 remain to be used in the embodiment of FIG. 2, where the same or similar reference numerals are used to refer to the same or similar elements, and the description of the same technical contents are omitted. Reference may be made to the embodiments above for the description of the omitted part, which will not be repeated here.

With reference to FIG. 2, the main difference between a heat dissipation substrate 20 of FIG. 2 and the heat dissipation substrate 10 of FIG. 1 is that the heat dissipation substrate 20 further includes a second circuit layer 140 disposed on the second surfaces of the plurality of heat dissipation blocks 100 (e.g., the second surface 102b of the heat dissipation block 102 and the second surface 104b of the heat dissipation block 104). A material of the second circuit layer 140 may be similar to the material of the first circuit layer 130.

In an embodiment, the second circuit layer 140 includes a first opening O1, and the first opening O1 exposes the second insulating surface 110b of part of the insulation filling structure 110. In addition, the second circuit layer 140 may be in direct contact with the second surface 102b of the heat dissipation block 102 and in direct contact with the second surface 104b of the heat dissipation block 104.

FIG. 2 schematically shows only the second circuit layer 140, but it is not intended to limit the disclosure. The wiring design of the second circuit layer 140 may be adjusted depending on the actual requirements. For example, a part of the second circuit layer 140 may serve as a signal conduction path between elements, and another part of the second circuit layer 140 may serve as a heat dissipation path.

Since the heat dissipation substrate 20 include circuit layers (i.e., the first circuit layer 130 and the second circuit layer 140) connected to the heat dissipation block 100 on both sides, packaging elements or heat-generating elements (not shown) may be disposed on the first circuit layer 130 or/and the second circuit layer 140 in the application to the packaging process. In other words, the heat dissipation substrate 20 may be elastically applied to the layout and connection of the packaging elements or the heat-generating elements, and may provide good heat dissipation in the meantime.

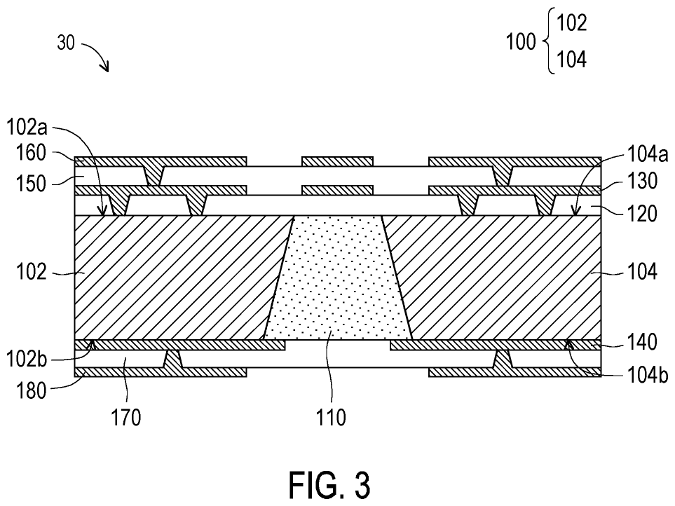

FIG. 3 is a schematic cross-sectional view of a heat dissipation substrate according to another embodiment of the disclosure. It should be noted here that the reference numerals and part of the contents of the embodiment of FIG. 2 remain to be used in the embodiment of FIG. 3, where the same or similar reference numerals are used to refer to the same or similar elements, and the description of the same technical contents are omitted. Reference may be made to the embodiments above for the description of the omitted part, which will not be repeated here.

With reference to FIG. 3, the main difference between a heat dissipation substrate 30 of FIG. 3 and the heat dissipation substrate 20 of FIG. 2 is that the heat dissipation substrate 30 includes a plurality of insulating layers and a plurality of circuit layers alternately stacked. To be specific, the heat dissipation substrate 30 includes the first insulating layer 120, the first circuit layer 130, a third insulating layer 150, and a third circuit layer 160 alternately stacked on the first surfaces of the plurality of heat dissipation blocks 100 (e.g., the first surface 102a of the heat dissipation block 102 and the first surface 104a of the heat dissipation block 104), and the second circuit layer 140, a fourth insulating layer 170, and a fourth circuit layer 180 alternately stacked on the second surfaces of the plurality of heat dissipation blocks 100 (e.g., the second surface 102b of the heat dissipation block 102 and the second surface 104b of the heat dissipation block 104). The third insulating layer 150 is disposed on the first insulating layer 120 and covers the first circuit layer 130. The third circuit layer 160 is disposed on the third insulating layer 150 and penetrates the third insulating layer 150 to be connected with the first circuit layer 130. The fourth insulating layer 170 is disposed on the second circuit layer 140 and covers the second circuit layer 140. The fourth circuit layer 180 is disposed on the fourth insulating layer 170 and penetrates the fourth insulating layer 170 to be connected with the second circuit layer 140. A material of the third insulating layer 150 and a material of the fourth insulating layer 170 may be similar to the material of the first insulating layer 120. A material of the third circuit layer 160 and a material of the fourth circuit layer 180 may be similar to the material of the first circuit layer 130.

In the application to the packaging process, packaging elements or the heat-generating elements may be disposed on the third circuit layer 160 or/and the fourth circuit layer 180 to transfer heat through the heat dissipation path formed by the corresponding first circuit layer 130 and the third circuit layer 160, or through the heat dissipation path formed by the second circuit layer 140 and the fourth circuit layer 180, to the heat dissipation block 100 to be dissipated.

FIG. 3 schematically shows only two circuit layers respectively disposed on the first surfaces and the second surfaces of the heat dissipation blocks, but it is not intended to limit the disclosure. The numbers of circuit layers on the first surface and the second surface of the heat dissipation block may be the same or different. The number of circuit layers and the number of insulating layers stacked on the heat dissipation block may be adjusted depending on the actual requirements.

Since the heat dissipation substrate 30 includes a plurality of insulating layers and a plurality of circuit layers alternately stacked, the heat dissipation substrate 30 may be more flexibly applied to the layout and connection of the packaging elements or the heat-generating elements, and may provide good heat dissipation in the meantime in the application to the packaging process.

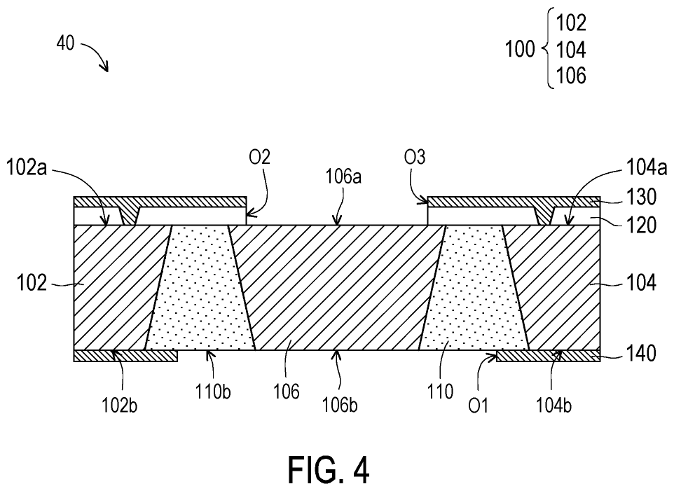

FIG. 4 is a schematic cross-sectional view of a heat dissipation substrate according to another embodiment of the disclosure. It should be noted here that the reference numerals and part of the contents of the embodiment of FIG. 2 remain to be used in the embodiment of FIG. 4, where the same or similar reference numerals are used to refer to the same or similar elements, and the description of the same technical contents are omitted. Reference may be made to the embodiments above for the description of the omitted part, which will not be repeated here.

With reference to FIG. 4, the main differences between a heat dissipation substrate 40 of FIG. 4 and the heat dissipation substrate 20 of FIG. 2 are that in the heat dissipation substrate 40, the first insulating layer 120 includes a second opening O2, the first circuit layer 130 includes a third opening O3, and the second opening O2 and the third opening O3 correspond to each other and expose the first surfaces of part of the plurality of heat dissipation blocks 100. For example, the plurality of heat dissipation blocks 100 include heat dissipation blocks 102, 104, and 106. The insulation filling structures 110 are disposed between adjacent heat dissipation blocks 100. For example, one insulation filling structure 110 is sandwiched between the heat dissipation blocks 102 and 106, and another insulation filling structure 110 is sandwiched between the heat dissipation blocks 106 and 104. The second opening O2 of the first insulating layer 120 and the third opening O3 of the first circuit layer 130 may expose a first surface 106a of part of the heat dissipation block 106. In other words, the heat dissipation block 106 is not connected to the first circuit layer 130.

In some embodiments, a sidewall of the second opening O2 of the first insulating layer 120 and a sidewall of the third opening O3 of the first circuit layer 130 are substantially aligned.

In some embodiments, the first opening O1 of the second circuit layer 140 may expose a second surface 106b of the heat dissipation block 106 and part of the second insulating surface 110b of the insulation filling structure 110, so that the heat dissipation block 106 is not connected to the second circuit layer 140. In other words, it is possible that part of the plurality of heat dissipation blocks 100 (e.g., the heat dissipation block 106) of the heat dissipation substrate 40 are not connected to the first circuit layer 130 and the second circuit layer 140.

In summary of the foregoing, in the heat dissipation substrate according to the embodiments of the disclosure, the packaging structure can be provided with good support and heat dissipation in the application to the packaging process. In addition, since it is not required to use a conventional supporting substrate, the manufacturing cost can be reduced. Moreover, in the heat dissipation substrate according to the embodiments of the disclosure, flexible wiring design may be performed in accordance with the requirements of different packaging elements or heat-generating elements in the package structure.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A heat dissipation substrate comprising:
a plurality of heat dissipation blocks, wherein each of the plurality of heat dissipation blocks comprises a first surface and a second surface opposite to the first surface;
an insulation filling structure disposed between the plurality of heat dissipation blocks to laterally connect the plurality of heat dissipation blocks, wherein the insulation filling structure has a first insulating surface and a second insulating surface opposite to the first insulating surface, the first insulating surface of the insulation filling structure is substantially coplanar with the first surfaces of the plurality of heat dissipation blocks, and the second insulating surface of the insulation filling structure is substantially coplanar with the second surfaces of the plurality of heat dissipation blocks;
a first insulating layer disposed on the first surfaces of part of the plurality of heat dissipation blocks and the first insulating surface of the insulation filling structure; and
a first circuit layer disposed on the first insulating layer and penetrating the first insulating layer to be connected with the plurality of heat dissipation blocks, wherein a thickness of the plurality of heat dissipation blocks is greater than a thickness of the first circuit layer.

2. The heat dissipation substrate according to claim 1, wherein the thickness of the plurality of heat dissipation blocks is between 50 μm and 200 μm, and the thickness of the first circuit layer is between 15 μm and 35 μm.

3. The heat dissipation substrate according to claim 1, wherein a material of the plurality of heat dissipation blocks comprises copper or aluminum.

4. The heat dissipation substrate according to claim 1, further comprising:
a second circuit layer disposed on the second surfaces of part of the plurality of heat dissipation blocks.

5. The heat dissipation substrate according to claim 4, wherein the second circuit layer comprises a first opening, and the first opening exposes at least the second insulating surface of part of the insulation filling structure.

6. The heat dissipation substrate according to claim 1, wherein the first insulating layer comprises a second opening, the first circuit layer comprises a third opening, and the second opening and the third opening correspond to each other and expose the first surfaces of part of the plurality of heat dissipation blocks.

7. The heat dissipation substrate according to claim 6, wherein a sidewall of the second opening of the first insulating layer and a sidewall of the third opening of the first circuit layer are substantially aligned.

8. The heat dissipation substrate according to claim 4, wherein part of the plurality of heat dissipation blocks are not connected to the first circuit layer and the second circuit layer.

9. The heat dissipation substrate according to claim 1, wherein a cross-sectional shape of the insulation filling structure comprises a rectangle or a trapezoid.

10. The heat dissipation substrate according to claim 1, wherein a material of the plurality of heat dissipation blocks and a material of the first circuit layer are the same.
